(19) United States
(12) Patent Application Publication
(10) Pub. No.: US 2024/0349585 A1
(43) Pub. Date: Oct. 17, 2024

(54) DRYING APPARATUSES AND DRYING METHODS USING THE SAME

(71) Applicant: Shenzhen China Star Optoelectronics Semiconductor Display Technology Co., Ltd., Shenzhen (CN)

(72) Inventor: Youyuan KUANG, Shenzhen (CN)

(73) Assignee: Shenzhen China Star Optoelectronics Semiconductor Display Technology Co., Ltd., Shenzhen (CN)

(21) Appl. No.: 18/536,377

(22) Filed: Dec. 12, 2023

(30) Foreign Application Priority Data
Apr. 12, 2023 (CN) 202310426923.2

(51) Int. Cl. H10K 71/40; F26B 5/04

(52) U.S. Cl. CPC H10K 71/441; F26B 5/04; B41J 11/00222

(57) ABSTRACT

The present disclosure provides a drying apparatus and a drying method using the same; the drying apparatus includes a housing, a supporting assembly, a pressure-reducing assembly, and a pressure-regulating assembly; the housing includes a drying chamber; the supporting assembly is disposed in the drying chamber and has a cavity, and the cavity includes a middle part and an edge part surrounding the middle part; the pressure-reducing assembly includes a extraction pipe communicated with the cavity; the pressure-regulating assembly includes a gas-guiding pipe communicated with the edge part; and the pressure-reducing assembly extracts a first gas from the cavity and the gas-guiding pipe is configured to supply a second gas into the edge part of the cavity.

### CROSS-REFERENCE TO RELATED APPLICATION

The present disclosure claims the priority to and benefit of Chinese Patent Application No. 202310426923.2 filed on Apr. 12, 2023, the disclosure of which is incorporated herein by reference in its entirety.

### TECHNICAL FIELD

The present disclosure relates to the field of vacuum drying, and in particular, to drying apparatuses and drying methods using the same.

### BACKGROUND

Organic light-emitting diode (OLED) devices have become a major trend in display technology due to their self-illumination, wide viewing angle, high contrast, fast response, thinness, and bendability. For the manufacture of large-size OLED devices and display devices, compared with vacuum hot evaporation technology, inkjet printing technology has the advantages of high material utilization rate (>98%), no need to use fine metal mask (FMM), and can be used to make large-size OLED display devices, so it has become the mainstream manufacturing solution for large-size OLED devices and display devices.

The inkjet printing process for preparing OLED devices mainly include the processes of printing→vacuum drying→baking. In the printing process, ink is printed in pixels; in the vacuum drying (VCD) process, solvents in the printed ink (hereafter “ink”) are evaporated under vacuum to form a solid film; and in the baking process, the printed materials are cross-linked in a high-temperature environment, and then the residual solvents are removed from the film. In the above three processes, the VCD process is the key process in determining film formation, which directly affects film uniformity and is one of the key factors affecting luminous efficiency and lifespan of the OLED devices.

However, during the VCD process, due to the fact that the gas at the edge part of a vacuum chamber in a vacuum drying apparatus is first extracted, an evaporation rate of the solvents in the printed film layer at the edge part of the OLED substrate is faster than that of the solvents in the printed film layer at the middle part of the OLED substrate, resulting in the difference between the drying morphology of the printed film layer at the edge part of the OLED substrate and the drying morphology of the printed film layer at the middle part of the OLED substrate, thus causing uneven brightness (Mura) in different areas of the OLED devices when displaying images.

### SUMMARY

In a first aspect, embodiments of the present disclosure provide a drying apparatus, including:
a housing including a drying chamber;
a supporting assembly disposed in the drying chamber and having a cavity, in which the cavity includes a middle part and an edge part surrounding the middle part;
a pressure-reducing assembly including an extraction pipe communicated with the cavity; and
a pressure-regulating assembly including a gas-guiding pipe communicated with the edge part, in which the pressure-reducing assembly extracts a first gas from the cavity and the gas-guiding pipe is configured to supply a second gas into the edge part of the cavity.

In a second aspect, embodiments of the present disclosure further provide a drying method using the above-mentioned drying apparatus, including:
placing a substrate to be dried in the cavity, in which a middle part of the substrate to be dried is disposed in the middle part of the cavity, and an edge part of the substrate to be dried is disposed in the edge part of the cavity;
extracting the first gas from the cavity; and
injecting the second gas into the edge part of the cavity through the gas-guiding pipe.

### BRIEF DESCRIPTION OF THE DRAWINGS

In order to explain technical solutions in the embodiments of the present disclosure more clearly, the following contents will briefly introduce the drawings needed to be used in the description of the embodiments. Apparently, the drawings in the following description are only some embodiments of the present disclosure. For those skilled in the art, other drawings can be obtained from these drawings without paying creative effort.

FIG. 1 is a schematic structural diagram of a drying apparatus provided by some embodiments of the present disclosure.

FIG. 2 is another schematic structural diagram of a drying apparatus provided by some embodiments of the present disclosure.

FIG. 3 is another schematic structural diagram of a drying apparatus provided by some embodiments of the present disclosure.

FIG. 4 is a schematic structural diagram of a supporting assembly provided by some embodiments of the present disclosure.

FIG. 5 is a flowchart diagram of a drying method provided by some embodiments of the present disclosure.

### DETAILED DESCRIPTION

In combination with drawings in embodiments of the present disclosure, technical solutions in the embodiments of the present disclosure will be described clearly and completely. Apparently, the described embodiments are only part of the embodiments of the present disclosure, not all of them. Based on the embodiments of the present disclosure, all other embodiments obtained by those skilled in the art without creative effort belong to the scope of the present disclosure. In addition, it should be understood that specific embodiments described herein are only used to explain and illustrate the present disclosure and are not intended to limit the present disclosure. In the present disclosure, the directional terms, such as “up” and “down”, generally refer to upward and downward directions of the device, respectively, in actual use or working state, in particular directions in the drawings; and terms “inside” and “outside” are relative to the contour of the devices, unless otherwise described.

In the prior art, the vacuum drying process is used to remove the solvents from the ink in a substrate to be dried, such as an OLED substrate to be dried, leaving solutes of the link to form an OLED functional layer. However, during the vacuum drying process, the gas at the edge part of the substrate is first extracted, while the gas at the middle part of the substrate is later extracted, resulting in a faster drying rate of the ink in the edge part and a slower drying rate of the ink in the middle part. Due to the difference of drying rates, the morphology of the dried ink at the middle part and the morphology of the dried ink at the edge part are different, resulting in a display difference between the middle and edge areas of the substrate, commonly known as Corner Mura.

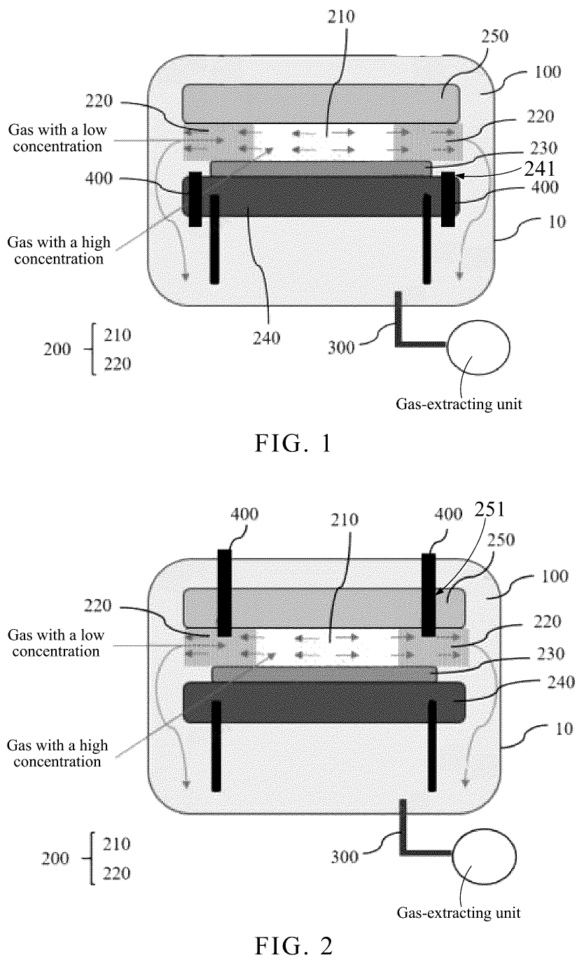

In order to reduce the difference in the morphology of the ink in different areas of the substrate after drying, some embodiments of the present disclosure provide a drying apparatus. As shown in FIG. 1, the drying apparatus includes a housing 10, a supporting assembly, a pressure-reducing assembly, and a pressure-regulating assembly. The housing 10 includes a drying chamber 100. The supporting assembly is disposed in the drying chamber 100, and the drying chamber 100 has a cavity 200. The cavity 200 includes a middle part 210 and an edge part 220 surrounding the middle part 210. The pressure-reducing assembly includes an extraction pipe 300 communicated with the cavity 200. The pressure-regulating assembly includes a gas-guiding pipe 400 communicated with the edge part 220. When the pressure-reducing assembly extracts a first gas from the cavity 200, the gas-guiding pipe 400 is configured to supply a second gas into the edge part 220 of the cavity 200.

In the embodiments of the present disclosure, by setting the pressure-reducing assembly and the pressure-regulating assembly in the drying apparatus, when the first gas in the cavity 200 is extracted by the extraction pipe 300 communicated with the cavity 200, the second gas can be synchronously supplied into the edge part 220 of the cavity 200 through the gas-guiding pipe 400, so that an extraction rate of a gas in the edge part 220 is equal to an extraction rate of a gas in the middle part 210 after the supplying, and drying rates in the middle and edge parts of the substrate to be dried that are placed in the cavity 200 are equivalent, thereby avoiding the technical problem of poor display effect of the substrate caused by the difference of drying rates.

Further, the second gas supplied by the gas-guiding pipe 400 is an inert gas. When the first gas in the cavity 200 is extracted, a concentration of an inert gas in the edge part 220 is greater than a concentration of an inert gas in the middle part 210.

When an inert gas is injected into the edge part 220, the concentration of the inert gas in the edge part 220 is greater than the concentration of the inert gas in the middle part 210. Although the first gas at the edge part 220 is preferentially extracted away than the first gas at the middle part 210, in some embodiments, by injecting the inert gas into the edge part 220, the injected inert gas can compensate part of the first gas that is preferentially extracted from the edge part 220 compared to the middle part 210. At this time, by controlling the flow rate of the injected inert gas, the extraction rates of gases in the edge part 220 and the middle part 210 can be achieved equally.

In some embodiments, the pressure-reducing assembly further includes an extraction unit communicated with the extraction pipe 300, for example, an extraction pump. The extraction unit is disposed outside the housing 10 and configured to extract the first gas from the drying chamber 100. The pressure-regulating assembly further includes a gas-supplying unit communicated with the gas-guiding pipe 400. The gas-supplying unit is disposed outside the housing 10 and configured to supply the second gas into the edge part 220 of the cavity 200. The supplied second gas is an inert gas, which may be selected from one of nitrogen, helium, and argon. Generally, nitrogen is selected as the inert gas to save costs.

Specifically, the supporting assembly includes a carrier platform 230, a temperature-controlling plate 240 disposed below the carrier platform 230, and a condensing plate 250 disposed above the carrier platform 230. The temperature-controlling plate 240 and the condensing plate 250 are disposed opposite to each other to form the cavity 200.

In some embodiments, the cavity 200 is a space formed by the temperature-controlling plate 240 and the condensing plate 250 that are disposed opposite to each other. The temperature-controlling plate 240 is in contact with the carrier platform 230. The regulation of the temperature of the carrier platform 230 can be achieved through the temperature-controlling plate 240, thereby achieving the regulation of the drying temperature of the substrate placed on the carrier platform 230.

It can be understood that, the temperature of the temperature-controlling plate 240 is set to be higher than that of the condensing plate 250. On the one hand, when the temperature of the temperature-controlling plate 240 is higher, the temperature of the carrier platform 230 in contact with the temperature-controlling plate 240 is also higher, which is conducive to the evaporation of the solvents from the ink in the substrate placed on the carrier platform 230. On the other hand, the evaporated solvents are cooled and condensed on the surface of the condensing plate 250, which can reduce the concentration of the gas formed by the evaporated solvents in the cavity 200, thereby facilitating the evaporation of the solvents from the ink in the substrate to form a functional layer.

In some embodiments, as shown in FIG. 1, an area of the temperature-controlling plate 240 is greater than an area of the carrier platform 230. Multiple first fixing holes 241 are provided surrounding the carrier platform 230 in a non-overlapping area of the temperature-controlling plate 240 and the carrier platform 230, and an outlet of each gas-guiding pipe 400 is fixed in one first fixing hole 241.

In some embodiments, the multiple first fixing holes 241 are uniformly arranged surrounding the carrier platform 230 on the temperature-controlling plate 240, and the number of gas-guiding pipes 400 is the same as the number of the first fixing holes 241. The outlet of each gas-guiding pipe 400 is fixed in one first fixing hole 241, so that the gas-guiding pipe 400 can stably supply the second gas from one side of the temperature-controlling plate 240 into the edge part 220 of the cavity 200.

In some embodiments, as shown in FIG. 2, multiple second fixing holes 251 are provided on the condensing plate 250, and the outlet of each gas-guiding pipe 400 is fixed in one second fixing hole 251.

The area of the condensing plate 250 may be greater than, less than, or equal to the area of the carrier platform 230, which is not limited in the present disclosure. In some embodiments, the number of the gas-guiding pipes 400 is the same as the number of the second fixing holes 251, and the outlet of each gas-guiding pipe 400 is fixed in one second fixing hole 251, so that the gas-guiding pipe 400 can stably supply the second gas from one side of the condensing plate 250 into the edge part 220 of the cavity 200.

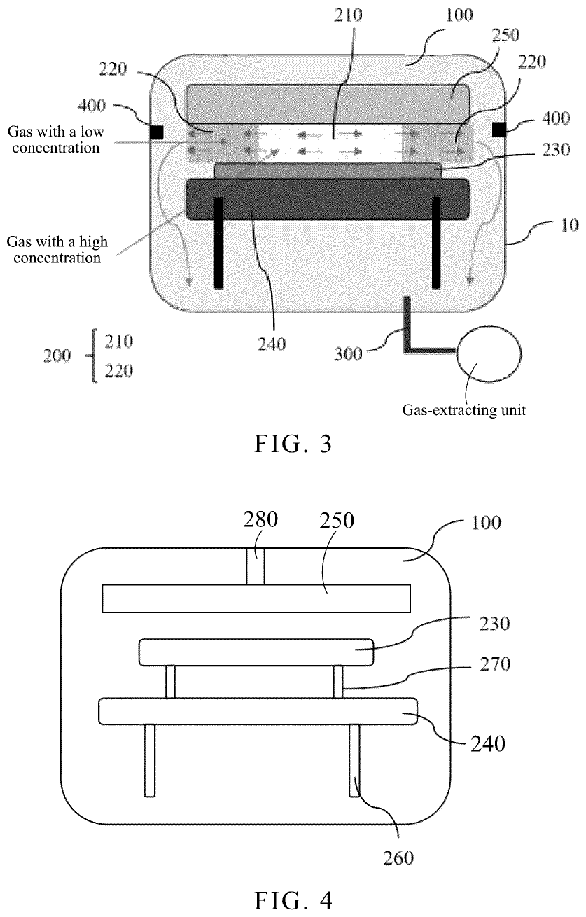

In some embodiments, as shown in FIG. 3, the outlet of the gas-guiding pipe 400 is fixed on an inner wall of the drying chamber 100, and an opening of the outlet is communicated with the edge part 220.

In some embodiments, the outlet of the gas-guiding pipe 400 may be fixed on the inner wall of the drying chamber 100 through a fixing member, and the opening of the outlet is communicated with the edge part 220, so as to supply the second gas into the edge part 220. Preferably, a horizontal height of the outlet ranges between a horizontal height of the temperature-controlling plate 240 and a horizontal height of the condensing plate 250.

It should be noted that the gas illustrated in each of FIG. 1, FIG. 2, and FIG. 3 indicate an injected inert gas.

Further, in some embodiments, as shown in FIG. 4, the supporting assembly further includes a first supporting member 260 disposed on a bottom surface of the drying chamber 100 for lifting and lowering the temperature-controlling plate 240, a second supporting member 270 disposed on the temperature-controlling plate 240 for lifting and lowering the carrier platform 230, and a first fixing member 280 disposed on the top of the drying chamber 100 for fixing the condensing plate 250.

It can be understood that, in order to facilitate the placement and removal of the substrate on the carrier platform 230, in some embodiments, heights of the temperature-controlling plate 240 and the carrier platform 230 are set to be adjustable. The lifting and lowering of the temperature-controlling plate 240 can be achieved through the first supporting member 260 disposed on the bottom surface of the drying chamber 100, and the lifting and lowering of the carrier platform 230 can be achieved through the second supporting member 270 disposed on the temperature-controlling plate 240. When it is necessary to remove or place the substrate, the height of the temperature-controlling plate 240 can be reduced through the first supporting member 260, and then the height of the carrier platform 230 can be reduced through the second supporting member 270, so as to reserve sufficient space for the removal or placement of the substrate. The heights mentioned above are based on the bottom surface of the drying chamber 100, that is, the adjusted height is the height relative to the bottom surface of the drying chamber 100. In some embodiments, the first supporting member 260 and the second supporting member 270 are lift pins.

In the above embodiments of the present disclosure, by setting the height of the temperature-controlling plate 240 to be adjustable, the adjustment to the cavity 200 formed by the temperature-controlling plate 240 and the condensing plate 250 can be achieved. Meanwhile, the different adjustments to the flow rates of the gases in the cavity 200 and the gas-guiding pipe 400 are conducive to achieving equal extraction rates of the gases in the edge part 220 and middle part 210 of the cavity 200.

In some embodiments, the drying apparatus further includes a monitoring assembly configured to monitor the pressure in the middle part 210 of the cavity 200 and the pressure in the edge part 220 of the cavity 200.

In some embodiments, in order to accurately achieve equalization of the extraction rates in the middle part 210 and the edge part 220 of the cavity 200, the pressures in the middle part 210 and the edge part 220 of the cavity 200 can be monitored by the monitoring assembly disposed in the drying cavity 100. It can be understood that, before the first gas is extracted, the pressures in the middle part 210 and the edge part 220 of the cavity 200 are the same, and after the first gas is extracted, the gas in the edge part 220 of the cavity 200 is preferentially extracted away than the gas in the middle part 210, resulting in more gas in the middle part 210 than in the edge part 220. That is, the pressure in the middle part 210 is greater than the pressure in the edge part 220, and by injecting the second gas into the edge part 220, the pressure in the edge part 220 can be effectively increased. Therefore, by setting the monitoring assembly to monitor the pressures at different positions of the cavity 200 through the monitoring assembly, it is beneficial to the real-time regulation of the airflow in the gas-guiding pipe 400.

Specifically, when the pressure in the edge part 220 is monitored to be less than the pressure in the middle part 210, the airflow in the gas-guiding pipe 400 can be injected or increased; and when the pressure in the edge part 220 is monitored to be greater than the pressure at the middle part 210, the airflow in the gas-guiding pipe 400 can be reduced or stopped.

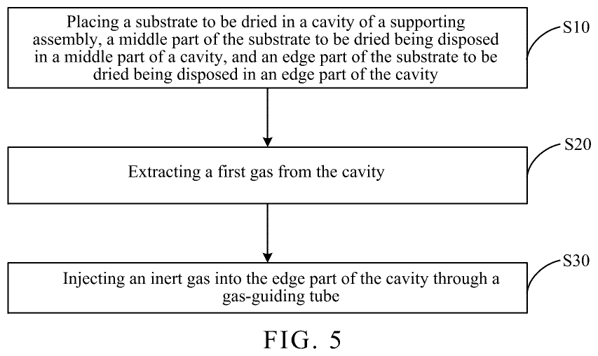

Moreover, some embodiments of the present disclosure further provide a drying method using the drying apparatus, as shown in FIG. 5, including the following steps:
step S10, placing the substrate to be dried in the cavity of the supporting assembly. A middle part of the substrate to be dried is disposed in the middle part of the cavity, and an edge part of the substrate to be dried is disposed in the edge part of the cavity;
step S20, extracting a first gas from the cavity; and
step S30, injecting an inert gas into the edge part of the cavity through the gas-guiding pipe.

In some embodiments of the present disclosure, after starting to extract the first gas from the cavity, the inert gas is immediately injected into the edge part of the cavity through the gas-guiding pipe. By supplementing the inert gas in the edge part of the cavity, the consistency of pressures in the edge part and middle part of the cavity can be effectively maintained, thereby ensuring the consistent evaporation rates of the solvents over the entire the substrate, and avoiding poor display performance of the prepared display substrate caused by the difference of evaporation rates of the solvents.

Specifically, the inert gas may be selected from at least one of nitrogen, argon, and helium, and a flow rate of the inert gas may range from 0 to 1000 sccm.

It can be understood that, in the embodiments, the inert gas is only used to balance the air pressure inside the cavity 200, so as to avoid the air pressure in the edge part 220 being less than the air pressure in the middle part 210, which is caused by more gas extracted from the edge part 220 than the middle part 210.

In this context, specific embodiments are used to illustrate the principles and implementation modes of the present disclosure. The description of the above-mentioned embodiments is only used to help understand core ideas of the present disclosure. At the same time, for those skilled in the art, according to the core ideas of the present disclosure, there might be changes in specific embodiments and the scope of the present disclosure, which falls within the scope of the protection of the present disclosure. The contents of the specification should not be interpreted as a limitation of the present disclosure.

What is claimed is:

1. A drying apparatus comprising:
a housing comprising a drying chamber;
a supporting assembly disposed in the drying chamber and having a cavity, wherein the cavity comprises a middle part and an edge part surrounding the middle part;
a pressure-reducing assembly comprising an extraction pipe communicated with the cavity; and
a pressure-regulating assembly comprising a gas-guiding pipe communicated with the edge part, wherein the pressure-reducing assembly extracts a first gas from the cavity and the gas-guiding pipe is configured to supply a second gas into the edge part of the cavity.

2. The drying apparatus of claim 1, wherein the second gas supplied by the gas-guiding pipe is an inert gas, wherein on a condition that the first gas in the cavity is extracted, a concentration of the inert gas in the edge part is greater than a concentration of the inert gas in the middle part.

3. The drying apparatus of claim 2, wherein the supporting assembly comprises a carrier platform, a temperature-controlling plate disposed below the carrier platform, and a condensing plate disposed above the carrier platform, wherein the temperature-controlling plate and the condensing plate are disposed opposite to each other to form the cavity.

4. The drying apparatus of claim 3, wherein an area of the temperature-controlling plate is greater than an area of the carrier platform; and a first fixing hole is provided surrounding the carrier platform in a non-overlapping area of the temperature-controlling plate and the carrier platform, and an outlet of the gas-guiding pipe is fixed in the first fixing hole.

5. The drying apparatus of claim 3, wherein a second fixing hole is provided on the condensing plate, and an outlet of the gas-guiding pipe is fixed in the second fixing hole.

6. The drying apparatus of claim 3, wherein an outlet of the gas-guiding pipe is fixed on an inner wall of the drying chamber, and an opening of the outlet is communicated with the edge part.

7. The drying apparatus of claim 3, wherein the supporting assembly further comprises a first supporting member disposed on a bottom surface of the drying chamber and configured to lift and lower the temperature-controlling plate, a second supporting member disposed on the temperature-controlling plate and configured to lift and lower the carrier platform, and a first fixing member disposed on a top of the drying chamber and configured to fix the condensing plate.

8. The drying apparatus of claim 7, wherein both of the first supporting member and the second supporting member are lift pins.

9. The drying apparatus of claim 1, further comprising a monitoring assembly configured to monitor a pressure in the middle part of the cavity and a pressure in the edge part of the cavity.

10. The drying apparatus of claim 1, wherein the pressure-reducing assembly further comprises a extraction unit communicated with the extraction pipe and disposed outside the housing.

11. The drying apparatus of claim 1, wherein the pressure-regulating assembly further comprises a gas-supplying unit communicated with the gas-guiding pipe and disposed outside the housing.

12. A drying method using the drying apparatus as claimed in claim 1, comprising:
placing a substrate to be dried in the cavity, wherein a middle part of the substrate to be dried is disposed in the middle part of the cavity, and an edge part of the substrate to be dried is disposed in the edge part of the cavity;
extracting the first gas from the cavity; and
injecting the second gas into the edge part of the cavity through the gas-guiding pipe.

13. The drying method of claim 12, wherein the second gas is an inert gas selected from at least one of nitrogen, argon, and helium.

14. The drying method of claim 12, wherein the second gas is an inert gas, and a flow rate of the inert gas ranges from 0 to 1000 sccm.

15. The drying method of claim 12, wherein the supporting assembly comprises a carrier platform, a temperature-controlling plate disposed below the carrier platform, and a condensing plate disposed above the carrier platform, wherein the temperature-controlling plate and the condensing plate are disposed opposite to each other to form the cavity.

16. The drying method of claim 15, wherein an area of the temperature-controlling plate is greater than an area of the carrier platform; and a first fixing hole is provided surrounding the carrier platform in a non-overlapping area of the temperature-controlling plate and the carrier platform, and an outlet of the gas-guiding pipe is fixed in the first fixing hole.

17. The drying method of claim 15, wherein a second fixing hole is provided on the condensing plate, and an outlet of the gas-guiding pipe is fixed in the second fixing hole.

18. The drying method of claim 15, wherein an outlet of the gas-guiding pipe is fixed on an inner wall of the drying chamber, and an opening of the outlet is communicated with the edge part.

19. The drying method of claim 12, wherein the supporting assembly further comprises a first supporting member disposed on a bottom surface of the drying chamber and configured to lift and lower the temperature-controlling plate, a second supporting member disposed on the temperature-controlling plate and configured to lift and lower the carrier platform, and a first fixing member disposed on a top of the drying chamber and configured to fix the condensing plate.

20. The drying method of claim 12, wherein the second gas is an inert gas, in the step of injecting the second gas into the edge part of the cavity through the gas-guiding pipe, a concentration of the inert gas in the edge part of the cavity is greater than a concentration of the inert gas in the middle part of the cavity.
